(19) United States
(12) Patent Application Publication
(10) Pub. No.: US 2024/0210822 A1
(43) Pub. Date: Jun. 27, 2024

(54) SWITCHABLE SUBSTRATE FOR EXTREME ULTRAVIOLET OR E-BEAM METALLIC RESIST

(71) Applicant: Taiwan Semiconductor Manufacturing Co., Ltd., Hsinchu (TW)

(72) Inventors: An-Ren Zi, Hsinchu (TW); Ching-Yu Chang, Hsinchu (TW)

(21) Appl. No.: 18/167,741

(22) Filed: Feb. 10, 2023

Related U.S. Application Data
(60) Provisional application No. 63/386,751, filed on Dec. 9, 2022.

(51) Int. Cl. G03F 7/004; G03F 7/09; H01L 21/308

(52) U.S. Cl. CPC G03F 7/0044; G03F 7/091; H01L 21/3081; H01L 21/3086

(57) ABSTRACT

A method for forming a semiconductor device is provided. The method includes forming a coating layer over a substrate, the coating layer comprising a switchable polymer comprising a polymer backbone and pendant groups attached to the polymer backbone and an acid generator. The pendant groups include acid labile groups and crosslinking groups. A baking process is then performed to cause crosslinking of the crosslinking groups to form a crosslinked coating layer. Next, a photoresist layer is deposited over the crosslinked coating layer. After selectively exposing the photoresist layer and the crosslinked coating layer to a patterning radiation, the selectively exposed photoresist layer and the crosslinked coating layer are developed to form a pattern of openings in the photoresist layer and the crosslinked coating layer.

### PRIORITY CLAIM AND CROSS-REFERENCE

This application claims benefit of U.S. Provisional Patent Application No. 63/386,751 filed Dec. 9, 2022, which is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for fabricating a semiconductor device, in accordance with some embodiments.

FIGS. 2A-2F are cross-sectional views of a semiconductor device fabricated using the method of FIG. 1, in accordance with some embodiments.

FIG. 3 illustrates an exemplary switchable polymer in a coating layer, in accordance with some embodiments.

FIG. 4A illustrates exemplary organometallic compounds, in accordance with some embodiments.

FIG. 4B illustrates an exemplary reaction of an organometallic compound in the presence of water, in accordance with some embodiments.

FIG. 5 illustrates an exemplary reaction of organometallic compounds, in accordance with some embodiments.

FIG. 6A illustrates exemplary cleavage reactions of acid labile groups of the switchable polymer, in accordance with some embodiments.

FIG. 6B illustrates exemplary condensation reactions between the organometallic compounds in the photoresist layer and the deprotected switchable polymers in the coating layer, in accordance with some embodiments.

FIG. 7 is a flow chart of a method for fabricating a semiconductor device, in accordance with some embodiments.

FIGS. 8A-8E are cross-sectional views of a semiconductor device fabricated using the method of FIG. 7, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. System may be otherwise oriented (rotated 90 degrees or at other orientations) and the spatially relative descriptors used herein may likewise be interpreted accordingly.

When describing the compounds, compositions, methods and processes of the present disclosure, the following terms have the following meanings, unless otherwise indicated.

As described herein, the compounds disclosed herein may optionally be substituted with one or more substituents, such as are illustrated generally below, or as exemplified by particular classes, subclasses, and species of the present disclosure. It will be appreciated that the phrase “optionally substituted” is used interchangeably with the phrase “substituted or unsubstituted.” In general, the term “substituted” whether proceeded by the term “optionally” or not, refers to the replacement of one or more hydrogen radicals in a given structure with the radical of a specified substituent. Unless otherwise indicated, an optionally substituted group may have a substituent at each substitutable position of the group. When more than one position in a given structure can be substituted with more than one substituent selected from a specified group, the substituent may be either the same or different at each position.
“Amino” refers to the —NH₂ group.
“Carboxy” refers to the —CO₂H group.
“Carbonyl” refers to —C═O group.
“Hydroxy” or “hydroxyl” refers to the —OH group.
“Oxo” refers to the ═O substituent group.
“Nitro” refers to the —NO₂ group.
“Alkyl” refers to a straight or branched hydrocarbon chain group consisting solely of carbon and hydrogen atoms, which is saturated or unsaturated (i.e., contains one or more double and/or triple bonds), having from one to twelve carbon atoms (C1-C12 alkyl), preferably one to eight carbon atoms (C1-C8 alkyl) or one to six carbon atoms (C1-C6 alkyl), and which is attached to the rest of the molecule by a single bond, e.g., methyl, ethyl, n-propyl, 1-methylethyl (iso-propyl), n-butyl, n-pentyl, 1,1-dimethylethyl (t-butyl), 3-methylhexyl, 2-methylhexyl, and the like. Unless stated otherwise specifically in the specification, an alkyl group may be optionally substituted.

“Alkylene” or “alkylene chain” refers to a straight or branched divalent hydrocarbon chain linking the rest of the molecule to a substituent group, consisting solely of carbon and hydrogen, which is saturated or unsaturated (i.e., contains one or more double and/or triple bonds), and having from one to twelve carbon atoms, e.g., methylene, ethylene, propylene, n-butylene, and the like. The alkylene chain is attached to the rest of the molecule through a single or double bond and to the substituent group through a single or double bond. The points of attachment of the alkylene chain to the rest of the molecule and to the substituent group can be through one carbon or any two carbons within the chain. Unless stated otherwise specifically in the specification, an alkylene chain may be optionally substituted.

“Alkoxy” refers to a group of the formula —ORa where Rₐ is an alkyl group as defined above containing one to twelve carbon atoms. Unless stated otherwise specifically in the specification, an alkoxy group may be optionally substituted.

“Alkylamino” refers to a group of the formula —NHRa or —NRₐRₐ where each Rₐ is, independently, an alkyl group as defined above containing one to twelve carbon atoms. Unless stated otherwise specifically in the specification, an alkylamino group may be optionally substituted.

“Amide” refers to the —NRₐR_{b} radical, wherein Rₐ and R_{b} are independently H, alkyl or aryl. Unless stated otherwise specifically in the specification, an amide group may be optionally substituted.

“Aryl” refers to a hydrocarbon ring system group comprising hydrogen, 6 to 18 carbon atoms and at least one aromatic ring. For purposes of this invention, the aryl group may be a monocyclic, bicyclic, tricyclic or tetracyclic ring system, which may include fused or bridged ring systems. Aryl groups include, but are not limited to, aryl groups derived from aceanthrylene, acenaphthylene, acephenanthrylene, anthracene, azulene, benzene, chrysene, fluoranthene, fluorene, as-indacene, s-indacene, indane, indene, naphthalene, phenalene, phenanthrene, pleiadene, pyrene, and triphenylene. Unless stated otherwise specifically in the specification, the term “aryl” or the prefix “ar-” (such as in “aralkyl”) is meant to include aryl groups that are optionally substituted.

“Cycloalkyl” or “carbocyclic ring” refers to a stable non-aromatic monocyclic or polycyclic hydrocarbon group consisting solely of carbon and hydrogen atoms, which may include fused or bridged ring systems, having from three to fifteen carbon atoms, preferably having from three to ten carbon atoms, and which is saturated or unsaturated and attached to the rest of the molecule by a single bond. Monocyclic cycloalkyl groups include, for example, cyclopropyl, cyclobutyl, cyclopentyl, cyclohexyl, cycloheptyl, and cyclooctyl. Polycyclic cycloalkyl groups include, for example, adamantyl, norbornyl, decalinyl, 7,7-dimethyl-bicyclo[2.2.1]heptanyl, and the like. Unless otherwise stated specifically in the specification, a cycloalkyl group may be optionally substituted.

“Halo” or “halogen” refers to bromo, chloro, fluoro or iodo.

“Haloalkyl” refers to an alkyl group, as defined above, that is substituted by one or more halo groups, as defined above, e.g., trifluoromethyl, difluoromethyl, trichloromethyl, 2,2,2-trifluoroethyl, 1,2-difluoroethyl, 3-bromo-2-fluoropropyl, 1,2-dibromoethyl, and the like. Unless stated otherwise specifically in the specification, a haloalkyl group may be optionally substituted.

“Heterocyclyl” or “heterocyclic ring” refers to a stable 3- to 18-membered non-aromatic ring group which consists of two to twelve carbon atoms and from one to six heteroatoms selected from the group consisting of nitrogen, oxygen and sulfur. Unless stated otherwise specifically in the specification, the heterocyclyl group may be a monocyclic, bicyclic, tricyclic or tetracyclic ring system, which may include fused or bridged ring systems; and the nitrogen, carbon or sulfur atoms in the heterocyclyl group may be optionally oxidized; the nitrogen atom may be optionally quaternized; and the heterocyclyl group may be partially or fully saturated. Examples of such heterocyclyl groups include, but are not limited to, dioxolanyl, thienyl[1,3]dithianyl, decahydroisoquinolyl, imidazolinyl, imidazolidinyl, isothiazolidinyl, isoxazolidinyl, morpholinyl, octahydroindolyl, octahydroisoindolyl, 2-oxopiperazinyl, 2-oxopiperidinyl, 2-oxopyrrolidinyl, oxazolidinyl, piperidinyl, piperazinyl, 4-piperidonyl, pyrrolidinyl, pyrazolidinyl, quinuclidinyl, thiazolidinyl, tetrahydrofuryl, trithianyl, tetrahydropyranyl, thiomorpholinyl, thiamorpholinyl, 1-oxo-thiomorpholinyl, and 1,1-dioxo-thiomorpholinyl. Unless stated otherwise specifically in the specification, a heterocyclyl group may be optionally substituted.

“N-heterocyclyl” refers to a heterocyclyl group as defined above containing at least one nitrogen and where the point of attachment of the heterocyclyl group to the rest of the molecule is through a nitrogen atom in the heterocyclyl group. Unless stated otherwise specifically in the specification, a N-heterocyclyl group may be optionally substituted.

“Heterocyclylalkyl” refers to a group of the formula —RbRe where R_{b} is an alkylene chain as defined above and Re is a heterocyclyl group as defined above, and if the heterocyclyl is a nitrogen-containing heterocyclyl, the heterocyclyl may be attached to the alkyl group at the nitrogen atom. Unless stated otherwise specifically in the specification, a heterocyclylalkyl group may be optionally substituted.

“Heteroaryl” refers to a 5- to 14-membered ring system group comprising hydrogen atoms, one to thirteen carbon atoms, one to six heteroatoms selected from the group consisting of nitrogen, oxygen and sulfur, and at least one aromatic ring. For purposes of this invention, the heteroaryl group may be a monocyclic, bicyclic, tricyclic or tetracyclic ring system, which may include fused or bridged ring systems; and the nitrogen, carbon or sulfur atoms in the heteroaryl group may be optionally oxidized; the nitrogen atom may be optionally quaternized. Examples include, but are not limited to, azepinyl, acridinyl, benzimidazolyl, benzothiazolyl, benzindolyl, benzodioxolyl, benzofuranyl, benzooxazolyl, benzothiazolyl, benzothiadiazolyl, benzo[b][1,4]dioxepinyl, 1,4-benzodioxanyl, benzonaphthofuranyl, benzoxazolyl, benzodioxolyl, benzodioxinyl, benzopyranyl, benzopyranonyl, benzofuranyl, benzofuranonyl, benzothienyl (benzothiophenyl), benzotriazolyl, benzo[4,6]imidazo[1,2-a]pyridinyl, carbazolyl, cinnolinyl, dibenzofuranyl, dibenzothiophenyl, furanyl, furanonyl, isothiazolyl, imidazolyl, indazolyl, indolyl, indazolyl, isoindolyl, indolinyl, isoindolinyl, isoquinolyl, indolizinyl, isoxazolyl, naphthyridinyl, oxadiazolyl, 2-oxoazepinyl, oxazolyl, oxiranyl, 1-oxidopyridinyl, 1-oxidopyrimidinyl, 1-oxidopyrazinyl, 1-oxidopyridazinyl, 1-phenyl-1H-pyrrolyl, phenazinyl, phenothiazinyl, phenoxazinyl, phthalazinyl, pteridinyl, purinyl, pyrrolyl, pyrazolyl, pyridinyl, pyrazinyl, pyrimidinyl, pyridazinyl, quinazolinyl, quinoxalinyl, quinolinyl, quinuclidinyl, isoquinolinyl, tetrahydroquinolinyl, thiazolyl, thiadiazolyl, triazolyl, tetrazolyl, triazinyl, and thiophenyl (i.e., thienyl). Unless stated otherwise specifically in the specification, a heteroaryl group may be optionally substituted.

“N-heteroaryl” refers to a heteroaryl group as defined above containing at least one nitrogen and where the point of attachment of the heteroaryl group to the rest of the molecule is through a nitrogen atom in the heteroaryl group. Unless stated otherwise specifically in the specification, an N-heteroaryl group may be optionally substituted.

“Heteroarylalkyl” refers to a group of the formula —R_{b}R_{f} where R_{b} is an alkylene chain as defined above and Rr is a heteroaryl group as defined above. Unless stated otherwise specifically in the specification, a heteroarylalkyl group may be optionally substituted.

“Hydroxylalkyl” refers to an alkyl group comprising at least one hydroxyl substituent. The one or more —OH substituents may be on a primary, secondary or tertiary carbon atom. Unless stated otherwise specifically in the specification, hydroxyalkyl group may be optionally substituted.

“Hydroxylalkylether” refers to an alkylether group comprising at least one hydroxyl substituent. The one or more —OH substituents may be on a primary, secondary or tertiary carbon atom. Unless stated otherwise specifically in the specification, hydroxyalkylether group may be optionally substituted.

“Sulfonate” refers to the —OS(O)₂Rₐ group, wherein Rₐ is alkyl or aryl. Unless stated otherwise specifically in the specification, a sulfonate group may be optionally substituted.

The term “substituted” used herein means any of the above groups (i.e., alkyl, alkylene, alkoxy, alkylamino, amide, aryl, cycloalkyl, etc.) wherein at least one hydrogen atom is replaced by a bond to a non-hydrogen atoms such as, but not limited to: a halogen atom such as F, Cl, Br, and I; an oxygen atom in groups such as hydroxyl groups, alkoxy groups, and ester groups; a sulfur atom in groups such as thiol groups, thioalkyl groups, sulfone groups, sulfonyl groups, and sulfoxide groups; a nitrogen atom in groups such as amines, amides, alkylamines, dialkylamines, arylamines, alkylarylamines, diarylamines, N-oxides, imides, and enamines; a silicon atom in groups such as trialkylsilyl groups, dialkylarylsilyl groups, alkyldiarylsilyl groups, and triarylsilyl groups; and other heteroatoms in various other groups. “Substituted” also means any of the above groups in which one or more hydrogen atoms are replaced by a higher-order bond (e.g., a double- or triple-bond) to a heteroatom such as oxygen in oxo, carbonyl, carboxyl, and ester groups; and nitrogen in groups such as imines, oximes, hydrazones, and nitriles. For example, “substituted” includes any of the above groups in which one or more hydrogen atoms are replaced with —NR_{g}Rₕ, —NR_{g}C(═O)Rₕ, —NR_{g}C(═O)NR_{g}Rₕ, —NR_{g}C(═O)ORₕ, —NR_{g}SO₂Rₙ, —OC(═O)NR_{g}Rₕ, —OR_{g}, —SR_{g}, —SOR_{g}, —SO₂R_{g}, —OSO₂R_{g}, —SO₂OR_{g}, ═NSO₂R_{g}, and —SO₂NR_{g}Rₕ. “Substituted also means any of the above groups in which one or more hydrogen atoms are replaced with —C(═O)R_{g}, —C(═O)OR_{g}, —C(═O)NR_{g}Rₕ, —CH₂SO₂R_{g}, —CH₂SO₂NR_{g}Rₕ. In the foregoing, R_{g} and Rₕ are the same or different and independently hydrogen, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl. “Substituted” further means any of the above groups in which one or more hydrogen atoms are replaced by a bond to an amino, cyano, hydroxyl, imino, nitro, oxo, thioxo, halo, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl group. In addition, each of the foregoing substituents may also be optionally substituted with one or more of the above substituents.

IC fabrication uses one or more photolithography processes to transfer geometric patterns to a film or substrate. Geometric shapes and patterns on a semiconductor make up the complex structures that allow the dopants, electrical properties and wires to complete a circuit and fulfill a technological purpose. In a photolithography process, a photoresist is applied as a thin film to a substrate, and subsequently exposed to one or more types of radiation or light through a photomask. The photomask contains clear and opaque features that define a pattern which is to be created in the photoresist layer. Areas in the photoresist exposed to light transmitted through the photomask are made either soluble or insoluble in a specific type of solution known as a developer. In the case when the exposed regions are soluble, a positive image of the photomask is produced in the photoresist and this type of photoresist is called a positive photoresist. On the other hand, if the unexposed areas are dissolved by the developer, a negative image results in the photoresist and this type of photoresist is called a negative photoresist. The developer removes the more soluble areas, leaving the patterned photoresist in place. The resist pattern is then used as an etch mask in subsequent etching processes, transferring the pattern to an underlying material layer, thereby replicating the mask pattern in the underlying material layer. Alternatively, the resist pattern is then used as an ion implantation mask in subsequent ion implantation processes applied to the underlying material layer, such as an epitaxial semiconductor layer.

Extreme ultraviolet (EUV) lithography to achieve sub-20 nm half-pitch resolution is under development for mass production for next generation sub 5 nm node. EUV lithography requires a high performance photoresist with high sensitivity for cost reduction of the high-power expo sure source, and to provide good resolution of the image.

As feature size decreases below 40 nm pattern pitch, line width resolution suffers. Residual photoresist or scum in small pitch and high aspect ratio patterns is difficult to remove. To improve line width roughness (LWR) in EUV lithography operations, a coating layer including a switchable polymer having a polymer backbone and pendant acid labile groups and crosslinking groups attached to the polymer backbone is formed either under the photoresist layer or on top of the photoresist layer according to embodiments of the present disclosure. Upon radiation, the acid labile groups of the switchable polymer in the exposed regions of the coating layer are cleaved from the polymer backbone to generate reactive functional groups which react with the organometallic compounds in the photoresist layer to form covalent bonds therebetween. The coating layer thus helps to enhance the collapse window, reduce LWR, and tune the resist pattern profile shape. By using the coating layer under or above the photoresist layer, the collapse window can be enlarged about 0.5 nm to 2 nm, the LWR can be improved by more than 5%, and the resist pattern integrity can be improved by more than 10%. In some embodiments, the coating layer is formed under the photoresist layer and functions as a bottom anti-reflective coating (BARC). In some embodiments, the coating layer is formed on top of the photoresist layer and functions as a top anti-reflective coating (TARC).

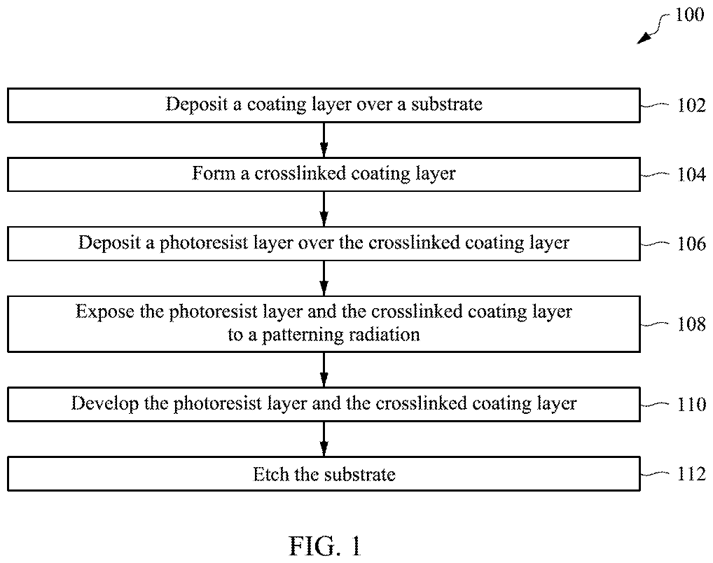

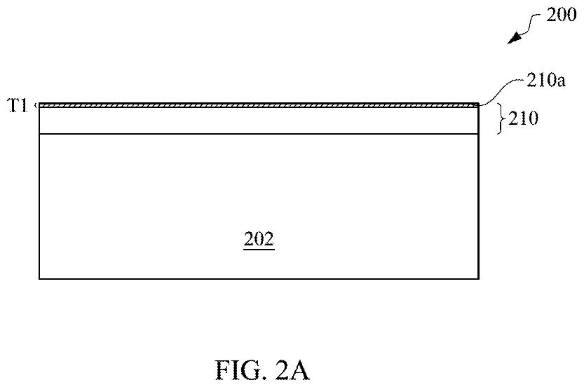

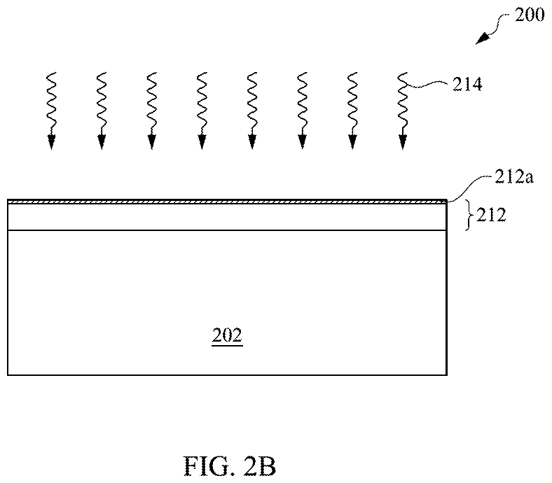

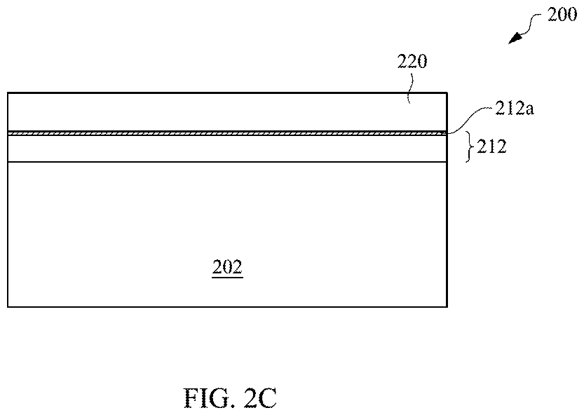

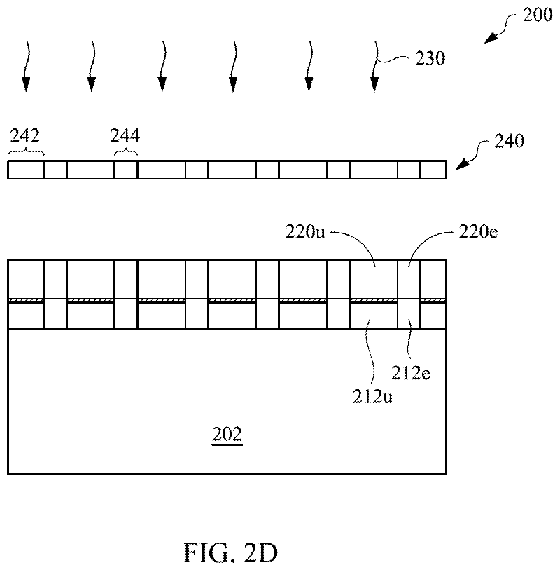

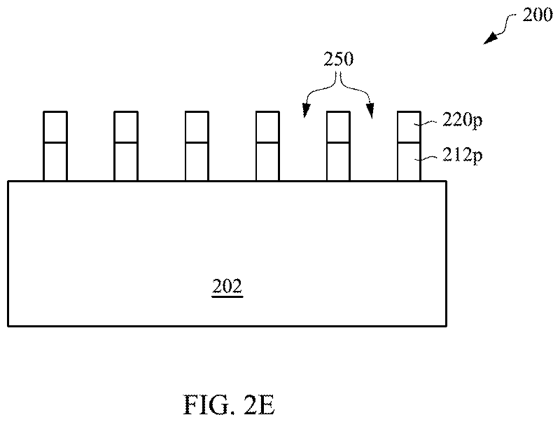

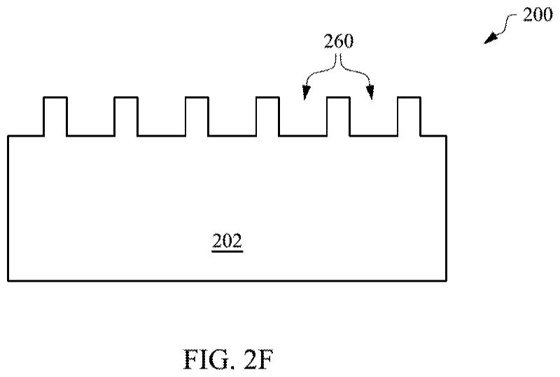

FIG. 1 is a flowchart illustrating a method 100 for forming a semiconductor device 200, in accordance with some embodiments of the present disclosure. FIGS. 2A through 2F are cross-sectional views of the semiconductor device 200 at various fabrication stages in accordance with some embodiments of the present disclosure. Intermediate steps of method 100 are described with reference to cross-sectional views of the semiconductor device 200 as shown in FIGS. 2A-2F. It is understood that additional steps can be provided before, during, and after the method 100, and some of the steps described below can be replaced or eliminated, for additional embodiments of the method. It is further understood that additional features can be added in the semiconductor device 200, and some of the features described below can be replaced or eliminated, for additional embodiments of the semiconductor device 200.

The semiconductor device 200 may be an intermediate structure during the fabrication of an IC, or a portion thereof. The IC may include logic circuits, memory structures, passive components (such as resistors, capacitors, and inductors), and active components such as diodes, field-effect transistors (FETs), metal-oxide semiconductor field effect transistors (MOSFETs), complementary metal-oxide semiconductor (CMOS) transistors, bipolar transistors, high voltage transistors, high frequency transistors, fin-like FETs (FinFETs), other three-dimensional (3D) FETs, and combinations thereof. The semiconductor device 200 may include a plurality of semiconductor devices (e.g., transistors), which may be interconnected.

Referring to FIGS. 1 and 2A, the method 100 includes operation 102, in which a coating layer 210 is formed over a substrate 202, in accordance with some embodiments. FIG. 2A is a cross-sectional view of the semiconductor device 200 after forming the coating layer 210 over the substrate 202, in accordance with some embodiments.

In some embodiments, the substrate 202 may be a bulk semiconductor substrate including one or more semiconductor materials. In some embodiments, the substrate 202 may include silicon, silicon germanium, carbon doped silicon (Si:C), silicon germanium carbide, or other suitable semiconductor materials. In some embodiments, the substrate 202 is composed entirely of silicon.

In some embodiments, the substrate 202 may include one or more epitaxial layers formed on a top surface of a bulk semiconductor substrate. In some embodiments, the one or more epitaxial layers introduce strains in the substrate 202 for performance enhancement. For example, the epitaxial layer includes a semiconductor material different from that of the bulk semiconductor substrate, such as a layer of silicon germanium overlying bulk silicon or a layer of silicon overlying bulk silicon geranium. In some embodiments, the epitaxial layer(s) incorporated in the substrate 202 are formed by selective epitaxial growth, such as, for example, metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), or combinations thereof.

In some embodiments, the substrate 202 may be a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or other suitable technique, such as wafer bonding and grinding.

In some embodiments, the substrate 202 may also include a dielectric substrate such as silicon oxide, silicon nitride, silicon oxynitride, a low-k dielectric, silicon carbide, and/or other suitable layers.

In some embodiments, the substrate 202 may also include various p-type doped regions and/or n-type doped regions, implemented by a process such as ion implantation and/or diffusion. Those doped regions include n-well, p-well, lightly doped region (LDD) and various channel doping profiles configured to form various IC devices, such as a CMOS transistor, imaging sensor, and/or light emitting diode (LED). The substrate 202 may further include other functional features such as a resistor and/or a capacitor formed in and/or on the substrate 202.

In some embodiments, the substrate 202 may also include various isolation features. The isolation features separate various device regions in the substrate 202. The isolation features include different structures formed by using different processing technologies. For example, the isolation features may include shallow trench isolation (STI) features. The formation of an STI may include etching a trench in the substrate 202 and filling in the trench with insulator materials such as silicon oxide, silicon nitride, and/or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

In some embodiments, the substrate 202 may also include gate stacks formed by dielectric layers and electrode layers. The dielectric layers may include an interfacial layer and a high-k dielectric layer deposited by suitable techniques, such as chemical vapor deposition (CVD), atomic layer deposition (ALD), physical vapor deposition (PVD), thermal oxidation, combinations thereof, and/or other suitable techniques. The interfacial layer may include silicon dioxide and the high-k dielectric layer may include LaO, AlO, ZrO, TiO, Ta₂O₅, Y₂O₃, SrTiO₃, BaTiO₃, BaZrO, HfZrO, HfLaO, HfSiO, LaSiO, AlSiO, HfTaO, HfTiO, (Ba,Sr)TiO₃ (BST), Al₂O₃, Si₃N₄, SiON, and/or other suitable materials. The electrode layer may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide). The electrode layer may include Ti, Ag, Al, TiAIN, TaC, TaCN, TaSiN, Mn, Zr, TiN, TaN, Ru, Mo, Al, WN, Cu, W, any suitable materials, and/or a combination thereof.

In some embodiments, the substrate 202 may also include a plurality of inter-level dielectric (ILD) layers and conductive features integrated to form an interconnect structure configured to couple the various p-type and n-type doped regions and the other functional features (such as gate electrodes), resulting in a functional integrated circuit. In one example, the substrate 202 may include a portion of the interconnect structure and the interconnect structure may include a multi-layer interconnect (MLI) structure and an ILD layer integrated with a MLI structure, providing an electrical routing to couple various devices in the substrate 202 to the input/output power and signals. The interconnect structure includes various metal lines, contacts and via features (or via plugs). The metal lines provide horizontal electrical routing. The contacts provide vertical connection between silicon substrate and metal lines while via features provide vertical connection between metal lines in different metal layers.

In some embodiments, the substrate 202 includes a dielectric layer. In some embodiments, the dielectric layer includes silicon oxide, silicon nitride, or silicon oxynitride. In some other embodiments, the dielectric material includes a metal oxide such as titanium oxide or a metal nitride such as titanium nitride.

The coating layer 210 is disposed on the substrate 202. In some embodiments, the coating layer 210 improves the adhesion of the photoresist layer to the substrate 202. In some embodiments, the coating layer 210 functions as a bottom anti-reflective coating (BARC). The BARC absorbs radiation that passes through the photoresist layer, thereby preventing the radiation from reflecting off the substrate 202 and exposing unintended portions of the photoresist layer. Thus, the BARC improves line width roughness and line edge roughness of the photoresist pattern.

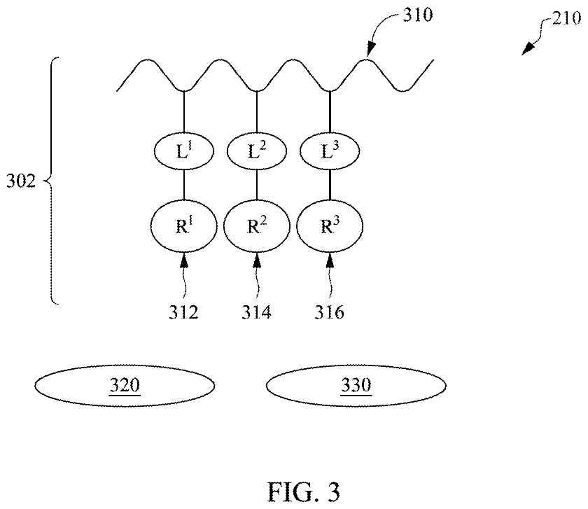

In some embodiments and as shown in FIG. 3, the coating layer 210 may include a switchable polymer 302, an acid generator 320, and a quencher 330.

The switchable polymer 302 has a polymer backbone 310 and multiple pendent group (e.g., groups 312, 314 and 316) attached to the polymer backbone 310. In some embodiments, the polymer backbone 310 is an organic polymer or an inorganic polymer. In some embodiments, the polymer backbone 310 (i.e., polymer main chain) is formed from one or more monomers selected from the group consisting of acrylates, acrylic acids, siloxanes, hydroxystyrenes, methacrylates, vinyl esters, maleicesters, methacrylonitriles, and methacrylamides.

In some embodiments, the functional groups that are attached to the polymer backbone 310 may include an acid labile group 312, a crosslinking group 314, and a floating group 316. The floating group 316 is optional and may be omitted in some embodiments. In some embodiments, additional functional groups may be bonded to the polymer backbone 310 and/or between the polymer backbone 310 and the functional groups 312, 314, and 316.

The acid labile group (ALG) 312 is attached to the polymer backbone 310 via linker L¹. The acid labile group 312 undergoes an acid-promoted deprotection reaction upon exposure to radiation and/or heat treatment, thereby producing a reactive group on the polymer side chain. In some embodiments, the acid labile group 312 which will decompose is derived from a carboxylic acid group, a fluorinated alcohol group, a phenolic alcohol group, a sulfonic group, a sulfonamide group, a sulfonylimido group, an (alkylsulfonyl)(alkylcarbonyl) methylene group, an (alkylsulfonyl)(alkyl carbonyl) imido group, bis(alkylcarbonyl) methylene group, a bis(alkylcarbonyl) imido group, a bis(alkylsulfonyl) methylene group, a bis(alkylsulfonyl) imido group, a tris(alkylcarbonyl) methylene group, a tris(alkylsulfonyl) methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like.

The acid labile group 312 is selected to be stable at the crosslinking temperature of the crosslinking group 314 and the photoresist pre-exposure baking temperature, so that the acid labile group 312 does not switch or decompose before exposure to radiation. For example, in instances where the crosslinking temperature is 215° C. and the photoresist pre-exposure baking temperature is 180 ºC, the acid labile group 312 needs to be stable at least at 215° C. In some embodiments, the acid labile group 312 is about 10 wt. % to about 70 wt. % of the switchable polymer 302. When the amount of the acid labile groups 312 is outside the disclosed ranges, there may not be an improvement in the line-width roughness and scum reduction.

The crosslinking group 314 is attached to the polymer backbone 310 via linker L². The crosslinking groups 314 on two polymer chains can react to bond two polymer chains together to improve the solvent resistance of the coating layer 210, so that the coating layer 210 will not be dissolved by the solvent used to form the photoresist layer. The crosslinking group 314 is selected such that the activation energy of the crosslinking group 314 is lower than the activation energy of acid labile group 312, so that crosslinking of the switchable polymer 302 will not cause reaction or decomposition of the acid labile group 312. In some embodiments, the crosslinking group 314 is about 30 wt. % to about 70 wt. % of the switchable polymer 302. When the amount of the crosslinking group 314 is outside the disclosed ranges, there may not be an improvement in the line-width roughness and scum reduction.

The floating group 316 is attached to the polymer backbone 310 via linker L³. In some embodiments, L³ is absent and the floating group 316 is directly connected to the polymer backbone 310. The floating group 316 helps the switchable polymer 302 to float to the upper portion of the coating layer 210 during the coating and baking processes. In some embodiments, the floating group 316 includes a fluorine-containing functional group. In some embodiment, the floating group 316 is a fluoroalkyl group such as —CF₃, —C₂F₅, —C₃F₇ or —C₄F₉. In some embodiments, in instances where the acid labile group 312 includes a fluoroalkyl group that can make the switchable polymer 302 floatable, the floating group 316 is omitted from the polymer structure. If present, the floating group 316 is about 5 wt. % to about 40 wt. % of the switchable polymer 302. When the amount of the floating group 316 is outside the disclosed ranges, there may not be an improvement in the line-width roughness and scum reduction.

In some embodiments, the switchable polymer 302 has the following structure (I):

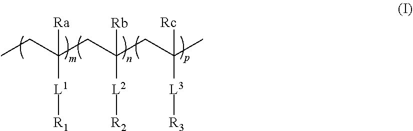

wherein:
L¹, L², and L³ are, at each occurrence, independently a direct bond or an C₁₋₁₀ alkylene, C₁₋₁₀ heteroalkylene, arylene, heteroarylene or heteroatom linker.
Rₐ, R_{b}, and R_{c} are, at each occurrence, independently hydrogen, C₁₋₁₀ alkyl or halogen;
R¹ is, at each occurrence, an acid labile group;
R² is, at each occurrence, a crosslinking group;
R³ is, at each occurrence, a floating group;
m and n are independently an integer of 1 or greater; and
p is an integer of 0 or greater.

In some embodiments, Rₐ, R_{b}, and R_{c} are independently hydrogen or methyl.

In some embodiments, R¹ has one of the following structures:

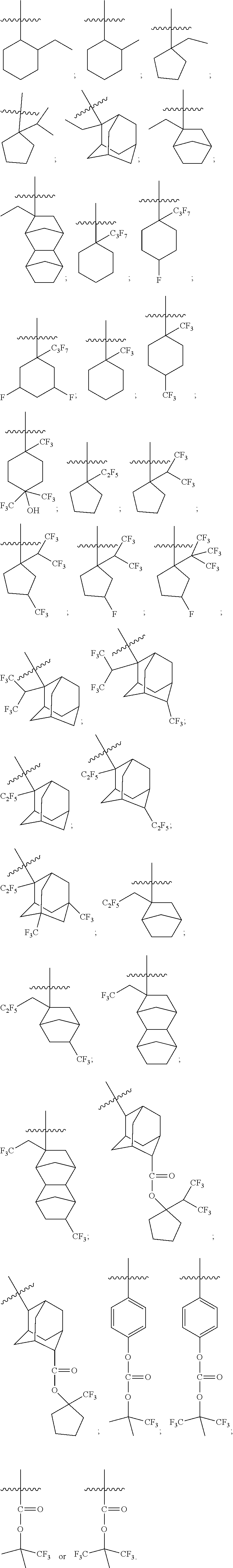

In some embodiments, R² has one of the following structures:

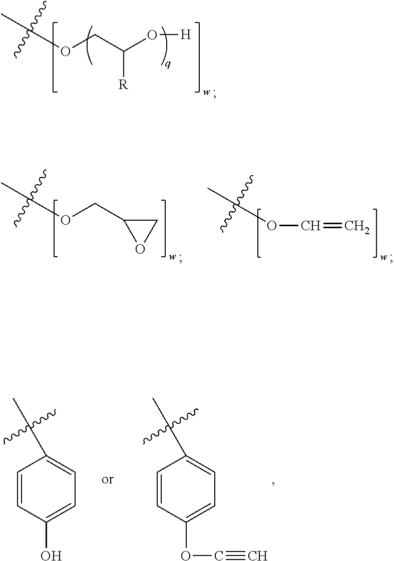

wherein:
R is, at each occurrence, hydrogen or a C₁₋₁₀ alkyl group;
q is an integer of 1 to 300; and
w is an integer of 1 to 6.

In some specific embodiments, R is a methyl, ethyl, propyl, isopropyl, n-butyl and n-pentyl group.

R³ is a CₓF_{y} containing group. The CₓF_{y} may contain a straight or branched chain. The number of carbons (x) may be from one (1) to nine (9). The number of fluorine (y) may be equal to 2x+1 or 3x. In some embodiments, R³ has one of the following structures:

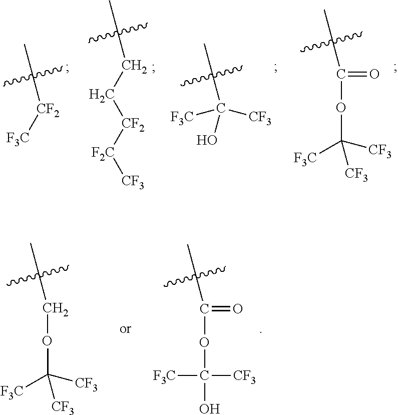 [SMILES: *C(F)(F)C(F)(F)F ; *CCC(F)(F)C(F)(F)C(F)(F)F ; *C(O)(C(F)(F)F)C(F)(F)F ; *C(=O)OC(C(F)(F)F)(C(F)(F)F)C(F)(F)F ; *COC(C(F)(F)F)(C(F)(F)F)C(F)(F)F ; *C(=O)OC(O)(C(F)(F)F)C(F)(F)F]

In some embodiments, L¹, L², and L³ are independently a substituted or unsubstituted, branched or unbranched, cyclic or noncyclic group and include saturated 1-9 carbon cyclic or non-cyclic group unsubstituted or substituted with halogen (e.g., alkene), —S—, —P—, —P(O₂)—, —C(═O)S—, —C(═O)O—, O—, —N—, —C(═O)N—,—SO₂O—,—SO₂S—,—SO—,—SO₂—,—C₆H₆—O—, —C₆H₆—O—C(═O)O—, or an ether, ketone, ester or phenylene group.

In some embodiments, L¹, L², or L³ independently has one of the following structures:

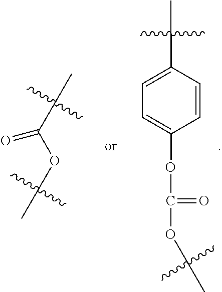 [SMILES: *OC(*)=O ; *OC(=O)Oc1ccc(*)cc1]

The acid generator 320 is dispersed within the coating layer 210. The acid generator 320 is selected to have sufficient thermal stability to withstand high temperatures used in heating processes the coating layer 210 is subjected to during processing (e.g., thermal treatment to crosslink the crosslinking group 314 and/or bake the photoresist).

In some embodiments, the acid generator 320 is a photoacid generator (PAG) that generates an acid when exposing to radiation, for example, EUV radiation or E-beam radiation. The photoacid generator may include a combination of a cation and an anion in some embodiments. Examples of photoacid generators according to embodiments of the disclosure include a-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-a-(p-toluenesulfonyloxy) acetate and t-butyl-a-(p-toluenesulfonyloxy) acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl) sulfonate and bis-(di-t-butylphenyl) iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-t-butylphenyl) iodonium triflate; pyrogallol derivatives (e.g., trimesylate of pyrogallol), trifluoromethanesulfonate esters of hydroxyimides, a,a′-bis-sulfonyl-diazomethanes, sulfonate esters of nitro-substituted benzyl alcohols, naphthoquinone-4-diazides, alkyl disulfones, or the like.

In some embodiments, the cation is selected from the group consisting of:

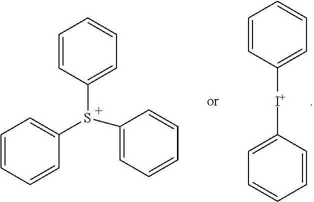

In some embodiments, the anion is selected from the group consisting of:

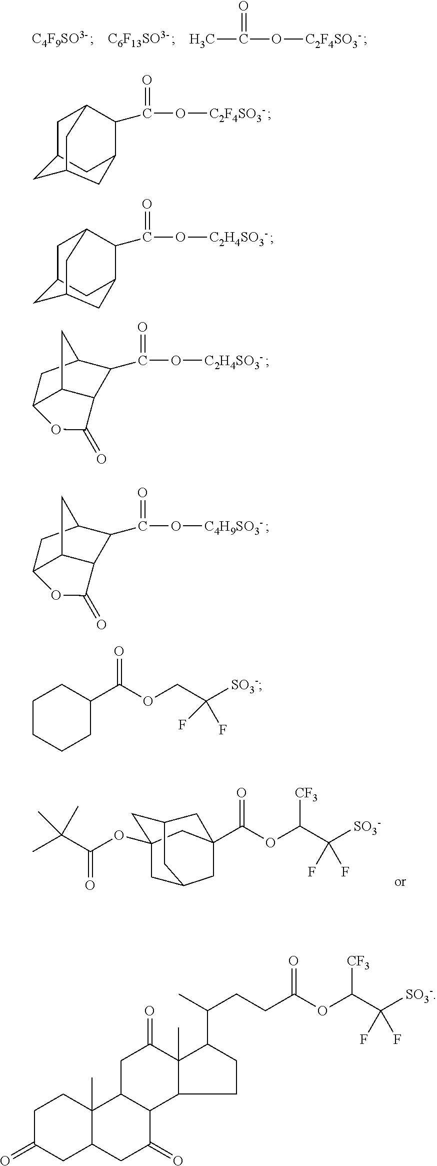

In some embodiments, the acid generator 320 is a thermal acid generator (TAG) that generates an acid upon heating. In some embodiments, the thermal acid generator is selected from the group consisting of:

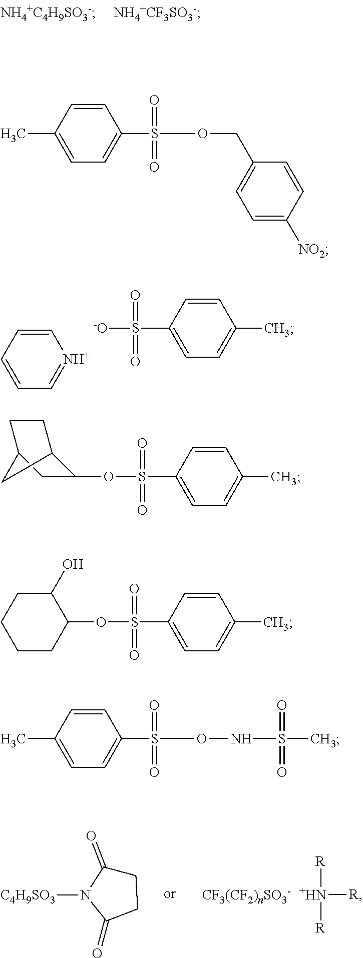

wherein:
R is H or alkyl; and
n is an integer of 1 to 6.

In some embodiments, the concentration of the acid generator 320 ranges from about 1 wt. % to about 20 wt. % based on the total weight of the coating composition. In other embodiments, the concentration of the acid generator 320 ranges from about 10 wt. % to about 15 wt. % based on the total weight of the coating composition. At concentrations of the acid generator 320 below the disclosed ranges, there may not be enough acid generated to improve the line width roughness and reduce scum. At concentrations of the acid generator 320 greater than the disclosed ranges, there may not be a significant improvement or there may be an increase in line width roughness and scum.

The quencher 330 is dispersed within the coating layer 210. The quencher 330 neutralizes excess acid generated by the radiation operation and subsequent post exposure baking operation, and thus inhibits the diffusion of the generated acid within the coating layer 210. The quencher 330 improves the resist pattern configuration as well as the stability of the photoresist over time. In some embodiments, the quencher 330 is an amine, such as a second lower aliphatic amine, a tertiary lower aliphatic amine, or the like. Specific examples of amines include trimethylamine, diethylamine, triethylamine, di-n-propylamine, tri-n-propylamine, tripentylamine, diethanolamine, and triethanolamine, alkanolamine, combinations thereof, or the like. In some embodiments, the quencher 330 has one of the following structures:

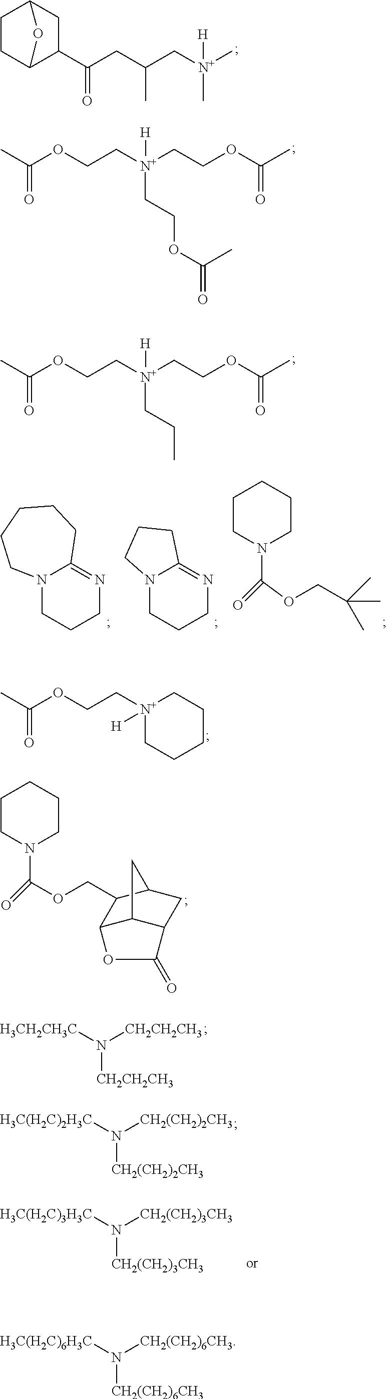

In some embodiments, the quencher 330 is a photodecomposable base (PDB) which generates a basic moiety in response to the radiation. The basic moiety generated by the photodecomposable base reacts with the generated acid, thereby preventing the generated acid from diffusing into portions of the coating layer 210 that are not exposed to the actinic radiation. The photodecomposable base may include a combination of a cation and an anion in some embodiments. In some embodiments, the photo-base generator has the following structure:

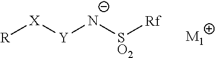

wherein:
R is an alkyl, heteroalkyl, cycloalkyl or heterocylic alkyl group;
X is carbonyloxy (—C(═O)O—);
Y is a linear, branched or cycloalkylene group or an arylene group;
Rf is a hydrocarbon group containing a fluorine atom; and
M₁^{⊕} represents an organic cation or a metal cation.

In some embodiments, R is selected from cyclopentyl, cyclohexyl, cycloheptyl, 4-methylcyclohexyl, cyclohexylmethyl, norbornyl, adamantyl, 2-oxocyclopentyl, 2-oxocyclohexyl, 2-cyclopentyl-2-oxoethyl, 2-cyclohexyl-2-oxoethyl, 2-(4-methylcyclohexyl)-2-oxoethyl, and 4-oxoadamantyl,

In some embodiments, Rf is trifluoromethyl.

In some embodiments, the cation is selected from one of the cations:

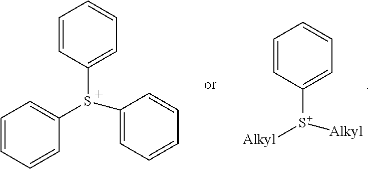

In some embodiments, the anion is selected from one of the following anions:

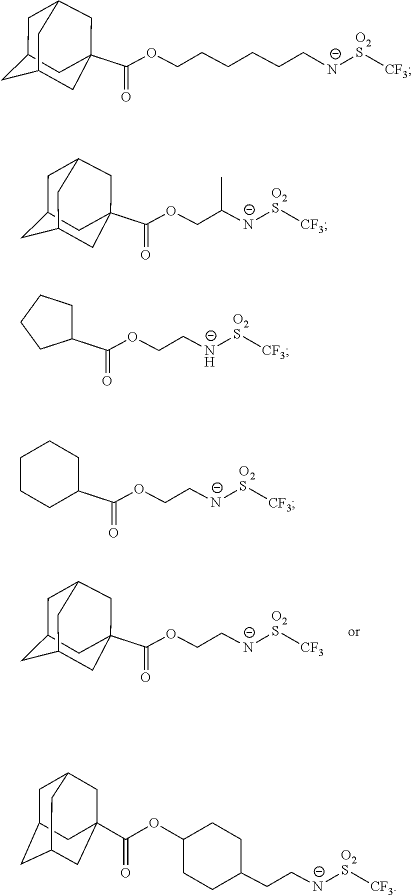 [SMILES: O=C(OCCCCCC[N-]S(=O)(=O)C(F)(F)F)C12CC3CC(CC(C3)C1)C2 ; CC(COC(=O)C12CC3CC(CC(C3)C1)C2)[N-]S(=O)(=O)C(F)(F)F ; O=C(OCC[N-]S(=O)(=O)C(F)(F)F)C1CCCC1 ; O=C(OCC[N-]S(=O)(=O)C(F)(F)F)C1CCCCC1 ; O=C(OCC[N-]S(=O)(=O)C(F)(F)F)C12CC3CC(CC(C3)C1)C2 ; O=C(OC1CCC(CC[N-]S(=O)(=O)C(F)(F)F)CC1)C12CC3CC(CC(C3)C1)C2]

In some embodiments, the concentration of the quencher 330 ranges from about 1 wt. % to about 20 wt. % based on the total weight of the coating composition. In other embodiments, the concentration of the quencher 330 ranges from about 10 wt. % to about 15 wt. % based on the total weight of the coating composition. At concentrations of the quencher 330 below the disclosed ranges, there may not be enough base to improve the line width roughness and reduce scum. At concentrations of the quencher 330 greater than the disclosed ranges, there may not be a significant improvement or there may be a decrease in line width roughness and scum reduction.

In some embodiments, the coating layer 210 may have a thickness ranging from about 2 nm to about 1 m. In some embodiments, the thickness of the coating layer 210 ranges from about 5 nm to about 500 nm, and in other embodiments, the thickness of the coating layer 210 ranges from about 10 nm to about 200 nm. Coating thicknesses less than the disclosed ranges may be insufficient to provide adequate photoresist adhesion and anti-reflective properties. Coating thicknesses greater than the disclosed ranges may be unnecessarily thick and may not provide further improvement in resist layer adhesion and scum reduction.

To form the coating layer 210, the individual components of the coating layer 210 including the switchable polymer 302, the acid generator 320, and the quencher 330 are placed into a solvent, and then the resulting coating composition is applied onto the top surface of the substrate 202, for example, by spin coating or by CVD, PVD, or ALD. The solvent can be any suitable solvent for dissolving the switchable polymer 302 and the selected coating components such as the acid generator 320, and the quencher 330. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK).

In some embodiments, the coating layer 210 may include a floating region 210a along a top surface of the coating layer 210. In some embodiments, the floating region 210a may include acid labile groups 312 and floating groups 316, if present. The floating region 210a is formed due to the movement of the acid labile groups 312 and floating groups 316 to the top of the coating layer 210 as the coating layer 210 is being applied, e.g., by spin coating. This movement is initiated because the addition of the fluorine atom causes the acid labile groups 312 and the floating groups 316 to have a high surface energy. This high surface energy, coupled with the low interaction between the fluorine atoms and the other atoms within the coating layer 210, initiate the movement of the acid labile groups 312 and the floating groups 316 to the top surface of the coating layer 210.

In embodiments with the formation of the floating region 210a, the floating region 210a will have a higher concentration of the acid labile groups 312 than a remainder of the coating layer 210 such as by having a concentration of between about 0.01% and about 10%, such as about 2%, while the remainder of the coating layer 210 (outside of the floating region 210a) will have a concentration of the acid labile groups 312 no greater than about 5%. In some embodiments, the floating region 210a will have a thickness Tl of between about 10 Å and about 1000 Å, such as about 100 Å. However, these dimensions and concentrations may vary and are intended to be illustrative only, and any benefits may be derived from suitable concentrations different from those listed herein.

Referring to FIGS. 1 and 2B, the method 100 proceeds to operation 104, in which the coating layer 210 is crosslinked to form a crosslinked coating layer 212, in accordance with some embodiments. FIG. 2B is a cross-sectional view of the semiconductor device 200 after forming the crosslinked coating layer 212, in accordance with some embodiments.

In some embodiments, a first baking process 214 is performed to remove the residue solvent from the coating layer 210 and to cause the crosslinking groups 314 to crosslink, thereby forming the crosslinked coating layer 212. In some embodiments, the crosslinked coating layer 212 includes a crosslinked floating region 212a along a top surface of the crosslinked coating layer 212. The first baking process 214 is performed at a temperature for a period of time that is sufficient to cause the crosslinking groups 314 to react with each other and to bond the individual polymer 301 into polymer networks; but does not cause the decomposition of the acid labile groups 312. In some embodiments, the baking or heating process 214 is performed at a temperature ranging from about 40° C. to about 300° C. In certain embodiments, the first baking process 214 is performed at a temperature of about 80° C. to about 200° C. for about 20 seconds to about 3 minutes. In other embodiments, the first baking process 214 is performed at a temperature of about 100° C. to about 250º C for about 10 seconds to about 2 minutes.

Referring to FIGS. 1 and 2C, the method proceeds to operation 106, in which a photoresist layer 220 is formed over the crosslinked coating layer 212, in accordance with some embodiments. FIG. 2C is a cross-sectional view of the semiconductor device 200 after forming the photoresist layer 220 over the crosslinked coating layer 212, in accordance with some embodiments.

The photoresist layer 220 is a photosensitive layer that is patternable by exposure to radiation. Typically, the chemical properties of the photoresist regions struck by incident radiation change in a manner that depends on the type of photoresist used. Photoresist layer 220 includes either a positive tone resist or a negative tone resist. A positive tone resist refers to a photoresist material that when exposed to radiation, such as UV light, becomes soluble in a developer, while the region of the photoresist that is non-exposed (or exposed less) is insoluble in the developer. A negative tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

In some embodiments, the photoresist layer 220 includes a high sensitivity photoresist composition. In some embodiments, the high sensitivity photoresist composition includes a metal that has a high absorbance of EUV radiation.

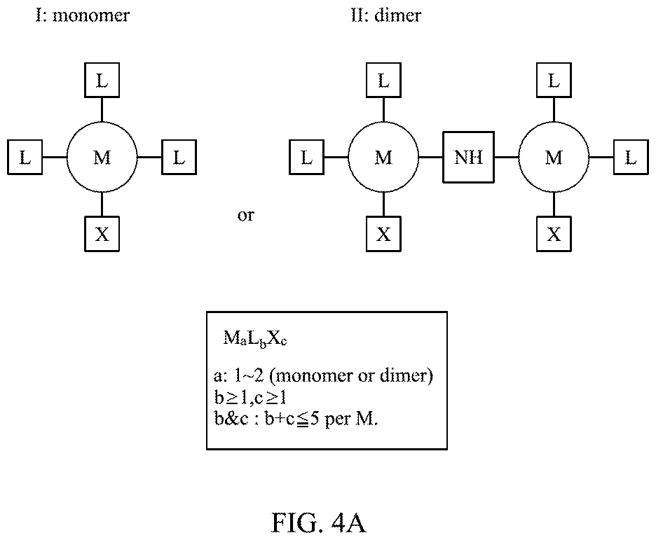

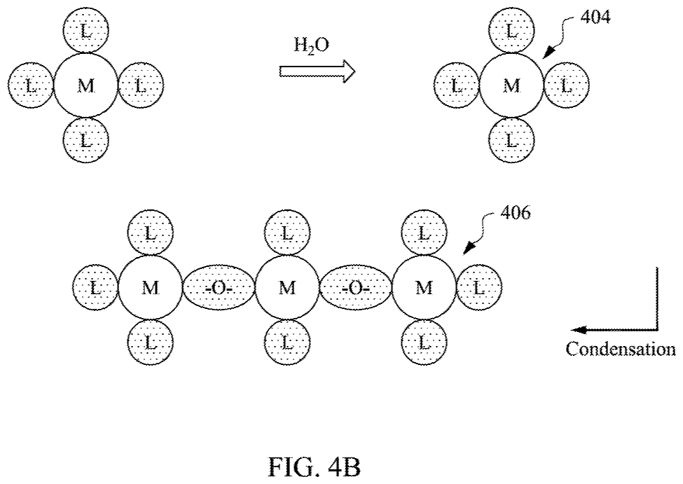

In some embodiments, the photoresist layer 220 may include an organometallic compound that includes a metallic core coordinated with multiple organic ligands. In some embodiments and as shown in FIG. 4A, the organometallic compound has the following formula:

MₐL_{b}X_{c},

wherein:

M is at least one of tin (Sn), bismuth (Bi), antimony (Sb), indium (In), tellurium (Te), titanium (Ti), zirconium (Zr), hafnium (Hf), vanadium (V), cobalt (Co), molybdenum (Mo), tungsten (W), aluminum (Al), arsenic (As), yttrium (Y), lanthanum (La), cerium (Ce), or lutetium (Lu);

L is independently a substituted or unsubstituted alkyl, alkenyl, cycloalkyl, cycloheteroalkyl, arylalkyl, aryl or heteroaryl;

X is independently a hydrolysable ligand; and

1≤a≤2, b≥1,c≥1, and b+c≤5.

In some embodiments, M is selected from the group consisting of Sn, Bi, Sb, In, Te, and combinations thereof. In some embodiments, L is a C3-C6 alkyl, alkenyl. In some embodiments, L is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. In some embodiments, L is fluorinated so that the alkyl or alkenyl group is substituted with one or more fluoro groups.

In some embodiments, X is any moiety readily reacting with a second compound to generate —OH, such as a moiety selected from the group consisting of amines, including dialkylamino and monalkylamino; alkoxy; carboxylates, halogens, and sulfonates. In some embodiments, the sulfonate group is substituted with one or more amine groups. In some embodiments, the halide is one or more selected from the group consisting of F, Cl, Br, and I. In some embodiments, the sulfonate group includes a substituted or unsubstituted C1-C3 group.

In some embodiments, the second compound is at least one of an amine, a borane, a phosphine, or water. In some embodiments, the amine has a formula NpHnXm, where 0≤n≤3, 0≤m≤3, n+m=3 when p is 1, and n+m-4 when p is 2, and each X is independently a halogen selected from the group consisting of F, Cl, Br, and I. In some embodiments, the borane has a formula BpHnXm, where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PₚHₙXₘ, where 0≤n≤3, 05≤m≤3, n+m=3, when p is 1, or n+m=4 when p is 2, and each X is independently a halogen selected from the group consisting of F, Cl, Br, and I.

In some embodiments, the second compound is water, ammonia, or hydrazine. The reaction product of the water, ammonia, or hydrazine and the organometallic compound may form hydrogen bonds that increase the boiling point of the reaction product and prevent emission of the metal photoresist material, thereby preventing metal contamination. The hydrogen bonds can also help prevent moisture effects to the photoresist layer quality.

FIG. 4B illustrates a reaction between an organometallic compound 402 and water. As shown in FIG. 4B, in the presence of water, the organometallic compound 402 is hydrolyzed, that is, the hydroxyl replaces the hydrolysable ligand and bond to the core M, resulting in a hydroxyl-containing compound 404. More than one hydroxyl-containing compound 404 may undergo a condensation reaction to form an organometallic polymer 406. It is noted that while the organometallic polymer 406 includes three organometallic compounds 402, organometallic polymers with less or more organometallic compounds 402 are envisioned.

In some embodiments, the organometallic compound includes a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy) tin, t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl(tris)dimethylamino tin, or n-propyl tris(butoxy) tin. In some embodiments, the organometallic compounds are fluorinated. In some embodiments, the organometallic compound has a boiling point less than about 200° C.

In some embodiments, the organometallic compound has one of the following structures:

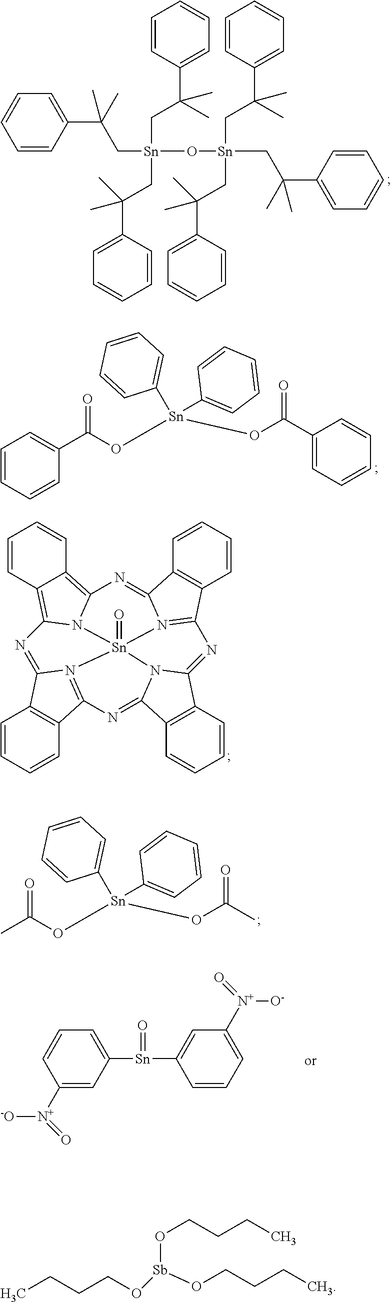

In some embodiments, the photoresist layer 220 is formed by applying a photoresist composition over the crosslinked coating layer 212 using, for example, spin coating. In some embodiments, the photoresist composition includes at least one kind of organometallic compounds and at least one kind of solvents. The amount of the organometallic compound in the photoresist composition may be from about 0.5% to 10% by weight. In some embodiments, the photoresist composition may include about 1% organometallic compound by weight.

In some embodiments, after the photoresist layer 220 is disposed over the crosslinked coating layer 212, a pre-exposure baking process may be performed to remove the solvent from the photoresist layer 220. The baking temperature is selected such that the pre-exposure baking process does not cause the cleavage of the acid labile group 312 of the switchable polymer 302 in the crosslinked coating layer 212. In some embodiments, the pre-exposure baking process may be performed at a temperature of about 40° C. to about 140° C. for 10 seconds to 5 minutes. In some embodiments, the photoresist layer 220 and the crosslinked coating layer 212 are heated at a temperature of about 60° C. to about 120º C for 20 seconds to 3 minutes.

Referring to FIGS. 1 and 2D, the method 100 proceeds to operation 108, in which the photoresist layer 220 and the crosslinked coating layer 212 are exposed to a radiation 230, in accordance with some embodiments. FIG. 2D is a cross-sectional view of the semiconductor device 200 after exposing the photoresist layer 220 and the crosslinked coating layer 212 to the radiation 230, in accordance with some embodiments.

The photoresist layer 220 and the crosslinked coating layer 212 are exposed to the radiation 230 from a light source through a photomask 240. The photomask 240 has a predefined pattern designed for an IC, based on a specification of the IC to be manufactured. The patterns of the photomask 240 correspond to patterns of materials that make up the various components of the IC device to be fabricated. For example, a portion of the IC design layout includes various IC features, such as an active region, gate electrode, source and drain, metal lines or vias of an interlayer interconnection, and openings for bonding pads, to be formed in the substrate 202.

In some embodiments, the photomask 240 includes first regions 242 and second regions 244. In the first regions 242, the radiation 230 is blocked by the photomask 240 to reach the photoresist layer 220 and the crosslinked coating layer 212, while in the second regions 244, the radiation 230 is not blocked by the photomask 240 and can pass through the photomask 240 to reach the photoresist layer 220 and the crosslinked coating layer 212. The photomask 240 thus is used to form exposed regions 220e and unexposed regions 220u of the photoresist layer, and exposed regions 212e and unexposed regions 212u of the crosslinked coating layer 212. In some embodiments, the exposure to radiation 230 is carried out by placing the photoresist-coated substrate 202 in a photolithography tool. The photolithography tool includes a photomask 240, optics, an exposure radiation source to provide the radiation 230 for exposure, and a movable stage for supporting and moving the substrate 202 under the radiation 230.

In some embodiments, the radiation 230 is an EUV radiation (e.g., 13.5 nm). Alternatively, in some embodiments, the radiation 230 is a DUV radiation (e.g., from a 248 nm KrF excimer laser or a 193 nm ArF excimer laser), X-ray radiation, an e-beam radiation, an ion beam radiation, or other suitable radiations. In some embodiments, operation 108 is performed in a liquid (immersion lithography) or in a vacuum for EUV lithography and e-beam lithography.

In some embodiments, the exposed regions 220e of the photoresist layer 220 that are irradiated by the radiation 230 undergo a further condensation reaction to form metallic clusters while the unexposed regions 220u that are not irradiated by the radiation 230 do not undergo the condensation reaction. The exposed regions 220e of the photoresist layer 220 may constitute a latent pattern. As the metallic clusters are substantially insoluble in a developer used in a later development process, the exposed regions 220e of the photoresist layer 220 that are irradiated by the radiation 230 are substantially insoluble in the developer. The unexposed regions 220u that are not irradiated by the radiation 230 do not undergo condensation reaction and are soluble in the developer. The difference in solubility allows the latent pattern to be developed in the developing process.

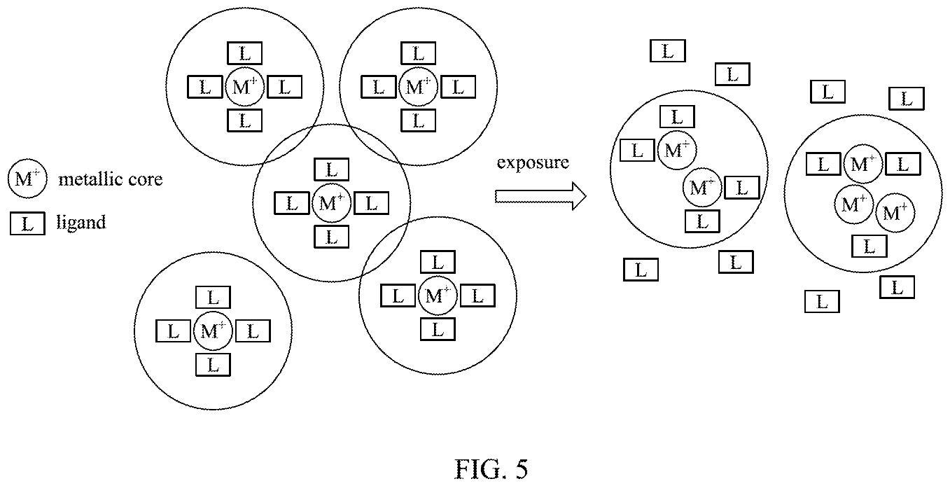

FIG. 5 shows a reaction that organometallic compounds undergo as a result of exposure to the radiation 230 in some embodiments. As a result of exposure to radiation 230, ligands L are cleaved from the metallic core M′ of the organometallic compounds, and two or more organometallic compound cores bond with each other to form the metal oxide cluster.

Upon radiation, the acid generator 320 such as PAGs or TAGs in the exposed regions 212e of the crosslinked coating layer 212 absorb the energy to generate an acid. The acid generated during the exposure to the radiation 230 cleaves acid labile groups (ALGs) from the crosslinked switchable polymer in the crosslinked coating layer 212, thereby forming reactive functional groups such as —COOH or —OH in the exposed regions 212e. The reactive functional groups in the crosslinked coating layer 212 then react with the hydroxyl group (OH) in the hydrolized organometallic compound (M-OH). The resulting covalent bonds formed between the photoresist layer 220 and the crosslinked coating layer 212 help to enhance the collapse window, LWR, and tune the resist profile shape.

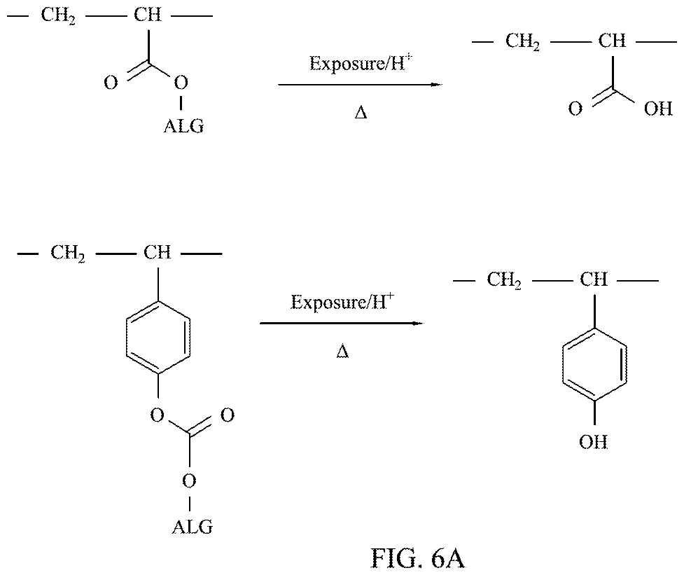

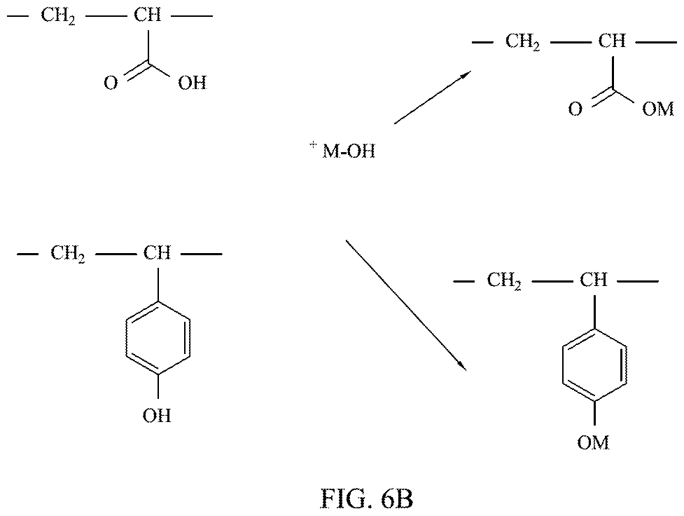

FIG. 6A illustrates a deprotection reaction of the acid labile group (ALG) 312 according to embodiments of the present disclosure. When the crosslinked coating layer 212 is exposed to the radiation 230, the acid generator 320 generates an acid (H) that cleaves the acid labile groups (ALG) 312, and producing a carboxyl (—COOH) or a hydroxyl group (—OH) on the polymer sidechain.

FIG. 6B illustrates a condensation reaction between the ALG-cleaved crosslinked switchable polymer and the hydrolyzed organometallic compound (M-OH).

Next, the photoresist layer 220 undergoes a post-exposure baking (PEB). In some embodiments, the photoresist layer 220 is heated at a temperature of about 50° C. to about 250° C. for about 20 seconds to about 300 seconds. In some embodiments, the post-exposure baking is performed at a temperature ranging from about 100° ° C. to about 230° C., and at a temperature ranging from about 150° ° C. to about 200° ° C. in other embodiments. During the PEB operation, more acid is generated in the exposed regions 212e of the crosslinked coating layer 212. The generated acid furthers the deprotection reaction of ALGs and the condensation reaction between the crosslinked coating layer 212 and the photoresist layer 220.

Referring to FIGS. 1 and 2E, the method 100 proceeds to operation 110, in which the photoresist layer 220 and the crosslinked coating layer 212 are developed to form a patterned photoresist layer 220p and a patterned crosslinked coating layer 212p, in accordance with some embodiments. FIG. 2E is a cross-sectional view of the semiconductor device 200 after developing the photoresist layer 220 and the crosslinked coating layer 212 to form the patterned photoresist layer 220p and the patterned crosslinked coating layer 212p, in accordance with some embodiments.

In some embodiments, the photoresist layer 220 is developed by applying a solvent-based developer to the photoresist layer 220. In some embodiments, the exposed regions 220e of the photoresist layer 220 undergo a metal cluster formation reaction as a result of the exposure to the radiation, and the unexposed regions 220u of the photoresist layer 220 are removed by the developer forming a pattern of openings 250 in the photoresist layer 220 to expose the substrate 202. In some embodiments, the crosslinked coating layer 212 disposed under the unexposed regions 220u of the photoresist layer 220 are removed during the development operation.

In some embodiments, the resist developer includes a solvent, and an acid or a base. In some embodiments, the concentration of the solvent is from about 60 wt. % to about 99 wt. % based on the total weight of the resist developer. The acid or base concentration is from about 0.001 wt. % to about 20 wt. % based on the total weight of the resist developer. In certain embodiments, the acid or base concentration in the developer is from about 0.01 wt. % to about 15 wt. % based on the total weight of the developer.

In some embodiments, the developer is applied to the photoresist layer 220 using a spin coating process. In the spin process, the developer is applied to the photoresist layer 220 from above the photoresist layer 220 while the photoresist-coated substrate 202 is rotated. In some embodiments, the developer is supplied at a rate of between about 5 ml/min and about 800 ml/min, while the photoresist coated substrate 202 is rotated at a speed of between about 100 rpm and about 2000 rpm. In some embodiments, the developer is at a temperature of between about 10° C. and about 80° C. The development operation continues for between about 30 seconds to about 10 minutes in some embodiments.

In some embodiments, the developer includes an organic solvent. The organic solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, 4-methyl-2-pentanol, acetone, methyl ethyl ketone, dimethylformamide (DMF), isopropanol (IPA), tetrahydrofuran (THF), methyl isobutyl carbinol (MIBC), n-butyl acetate (nBA), 2-heptanone (MAK), and dioxane.

While the spin coating operation is one suitable method for developing the photoresist layer 220 after exposure, it is intended to be illustrative and is not intended to limit the embodiment. Rather, any suitable development operations, including dip processes, puddle processes, and spray-on methods, may alternatively be used. All such development operations are included within the scope of the embodiments.

In some embodiments, a dry developer is applied to the photoresist layer 220. In some embodiments, the dry developer is a plasma or chemical vapor, and the dry development operation is a plasma etching or chemical etching operation. The dry development uses the differences related to the composition, extent of cross-linking, and film density to selectively remove the desired portions of the resist. In some embodiments, the dry development processes uses either a gentle plasma (high pressure, low power) or a thermal process in a heated vacuum chamber while flowing a dry development chemistry, such as BCl₃, BF₃, or other Lewis Acid in the vapor state. In some embodiments, the BCl₃ removes the unexposed material, leaving behind a pattern of the exposed film that is transferred into the underlying layers by plasma-based etch processes.

In some embodiments, the dry development includes plasma processes, including transformer coupled plasma (TCP), inductively coupled plasma (ICP) or capacitively coupled plasma (CCP). In some embodiments, the plasma process is conducted at a pressure of ranging from about 5 m Torr to about 20 mTorr, at a power level from about 250 W to about 1000 W, temperature ranging from about 0° ° C. to about 300° C., and at flow rate of about 100 to about 1000 sccm, for about 1 to about 3000 seconds.

In some embodiments, the photoresist is a negative-tone resist, and the unexposed regions 220u of the photoresist layer 220 are removed by the development operation. In other embodiments, the photoresist is a positive-tone resist, and the exposed regions 220e of the photoresist layer 220 are removed by the development operation.

Referring to FIGS. 1 and 2F, the method 100 proceeds to operation 112, in which the substrate 202 is etched using the patterned photoresist layer 220p and the patterned crosslinked coating layer 212p as an etch mask, in accordance with some embodiments. FIG. 2F is a cross-sectional view of the semiconductor device 200 after etching the substrate 202 using the patterned photoresist layer 220p and the patterned crosslinked coating layer 212p as an etch mask, in accordance with some embodiments.

As shown in FIG. 2F, the substrate 202 is patterned, using the patterned photoresist layer 220p as an etch mask, to form recesses 260 therein.

An etching process may be performed to transfer the pattern in the patterned photoresist layer 220p to the substrate 202. In some embodiments, the etching process employed is an anisotropic etch such as a dry etch although any suitable etch process may be utilized. In some embodiments, the dry etch is a reactive ion etch (RIE) or a plasma etch. In some embodiments, the dry etch is implemented by fluorine-containing gas (e.g., CF₄, SF₆, CH₂F₂, CHF₃, and/or C₂F₆), chlorine-containing gas (e.g., Cl₂, CHCI₃, CCl₄, and/or BCl₃), bromine-containing gas (e.g., HBr and/or CHBr₃), oxygen-containing gas, iodine-containing gas, other suitable gases and/or plasmas, or combinations thereof. In some embodiments, an oxygen plasma is performed to etch the substrate 202. In some embodiments, the anisotropic etch is performed at a temperature from about 250° C. to 450° C. for a duration from about 20 seconds to about 300 seconds.

If not completely consumed in the etching process, after formation of the recesses 260, the patterned photoresist layer 220p and the patterned crosslinked coating layer 212p are removed, for example, by plasma ashing or wet stripping.

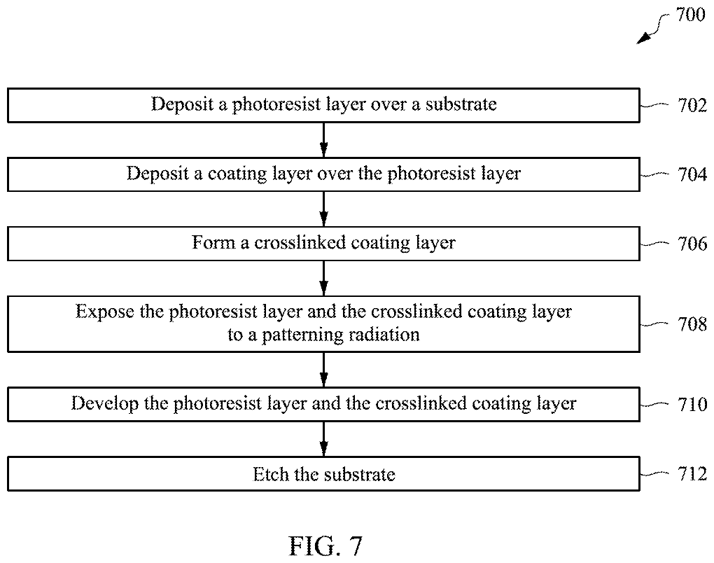

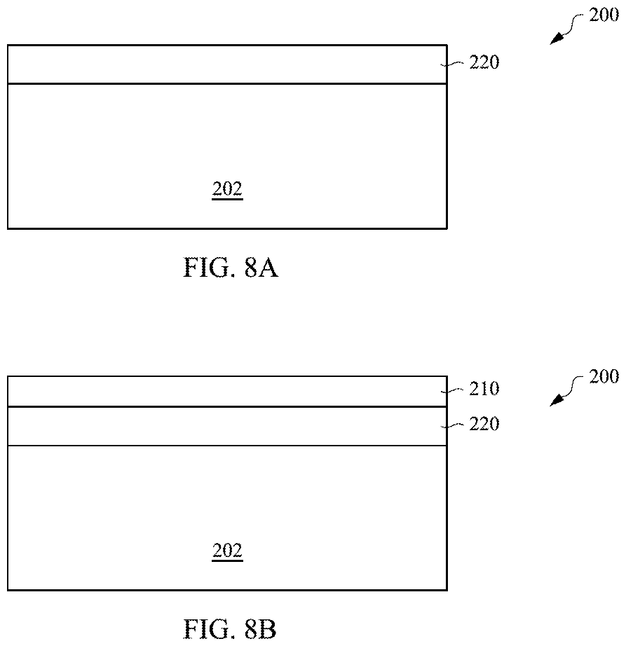

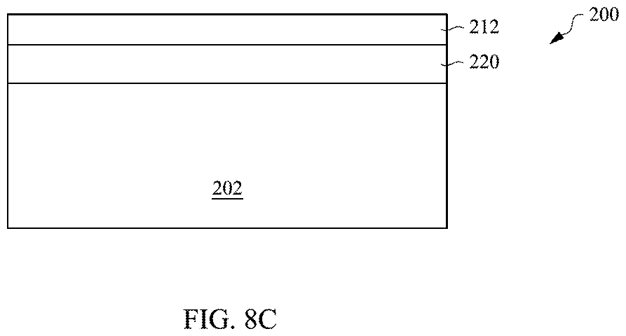

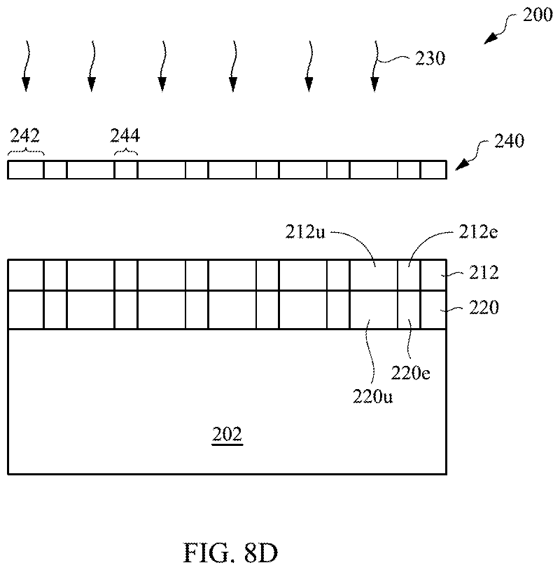

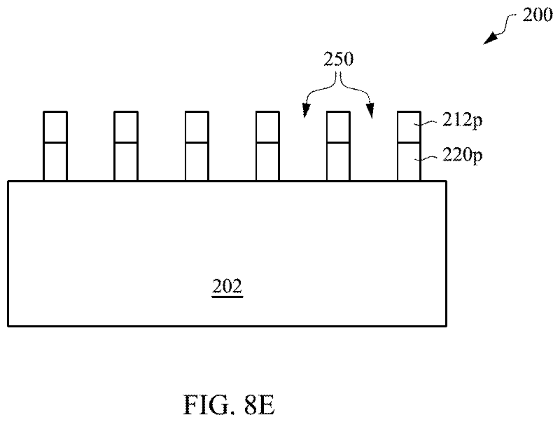

FIG. 7 is a flowchart illustrating a method 700 for forming the semiconductor device 200, in accordance with some embodiments of the present disclosure. FIGS. 8A through 8E are cross-sectional views of the semiconductor device 200 at various fabrication stages in accordance with some embodiments of the present disclosure. Intermediate steps of method 700 are described with reference to cross-sectional views of the semiconductor device 200 as shown in FIGS. 8A-8E. Unlike method 100 in which the coating layer 210 is formed as an underlayer beneath the photoresist layer, in method 700, the coating layer 210 is formed as a top coating layer over the photoresist layer 220. Unless specified otherwise, the materials and the formation methods of the components in these embodiments are essentially the same as their like components, which are denoted by like reference numerals in the embodiments shown in FIGS. 2A-2F. The details regarding the formation processes and the materials of the components shown in FIGS. 8A-8E are thus found in the discussion of the embodiments shown in FIGS. 2A-2E.

Referring to FIGS. 7 and 8A, the method 700 includes operation 702, in which a photoresist layer 220 is formed over a substrate 202, in accordance with some embodiments. FIG. 8A is a cross-sectional view of the semiconductor device 200 after forming the photoresist layer 220 over the substrate 202, in accordance with some embodiments. In some embodiments, the photoresist layer 220 includes an organometallic compound and is formed by fabrication process described above in FIG. 2C.

Referring to FIGS. 7 and 8B, the method 700 proceeds to operation 704, in which a coating layer 210 is formed over the photoresist layer 220, in accordance with some embodiments. FIG. 8B is a cross-sectional view of the semiconductor device 200 after forming the coating layer 210 over the photoresist layer 220, in accordance with some embodiments. In some embodiments, the coating layer 210 includes a switchable polymer 302, an acid generator 320 and a quencher 330 and is formed by fabrication process described above in FIG. 2A.

Referring to FIGS. 7 and 8C, the method 700 proceeds to operation 706, in which the coating layer 210 is heated to form a crosslinked coating layer 212, in accordance with some embodiments. FIG. 8C is a cross-sectional view of the semiconductor device 200 after forming the crosslinked coating layer 212, in accordance with some embodiments. In some embodiments, the crosslinked coating layer 212 is formed by fabrication process described above in FIG. 2B.

Referring to FIGS. 7 and 8D, the method 700 proceeds to operation 708, in which the crosslinked coating layer 212 and the photoresist layer 220 are exposed to radiation 230 to form exposed regions 212e and unexposed regions 212u in the crosslinked coating layer 212 and exposed regions 220e and unexposed regions 220u in the photoresist layer 220, in accordance with some embodiments. FIG. 8D is a cross-sectional view of the semiconductor device 200 after exposing the crosslinked coating layer 212 and the photoresist layer 220 to radiation 230, in accordance with some embodiments. In some embodiments, exposing the crosslinked coating layer 212 and the photoresist layer 220 to radiation 230 is performed by fabrication process described above in FIG. 2D.

Upon radiation, the acid generator 320 such as PAGs or TAGs in the exposed regions 212e of the crosslinked coating layer 212 absorb the energy to generate an acid. The acid generated during the exposure to the radiation 230 cleaves acid labile groups (ALGs) from the crosslinked switchable polymer in the crosslinked coating layer 212, thereby forming reactive functional groups such as —COOH or —OH in the exposed regions 212e. The reactive functional groups in the crosslinked coating layer 212 then react with the hydroxyl group (OH) in the hydrolyzed organometallic compound (M-OH). The resulting covalent bonds formed between the photoresist layer 220 and the crosslinked coating layer 212 help to enhance the collapse window, reduce LWR, and tune the resist profile shape.

Referring to FIGS. 7 and 8E, the method 700 proceeds to operation 710, in which the crosslinked coating layer 212 and the photoresist layer 220 are developed to form a patterned crosslinked coating layer 212p and a patterned photoresist layer 220p, in accordance with some embodiments. FIG. 8E is a cross-sectional view of the semiconductor device 200 after developing the crosslinked coating layer 212 and the photoresist layer 220 to form the patterned crosslinked coating layer 212p and the patterned photoresist layer 220p, in accordance with some embodiments. In some embodiments, the crosslinked coating layer 212 and the photoresist layer 220 are developed by fabrication process described above in FIG. 2E.

Referring to FIG. 7, the method 700 proceeds to operation 712, in which the substrate 202 is etched using the patterned crosslinked coating layer 212p and the patterned photoresist layer 220p, in accordance with some embodiments. In some embodiments, the substrate 202 is etched by fabrication process described above in FIG. 2F to afford an etched substrate as shown in FIG. 2F.

One aspect of this description relates to a method for forming a semiconductor device. The method includes forming a coating layer over a substrate, the coating layer including a switchable polymer and an acid generator. The switchable polymer includes a polymer backbone and pendant groups attached to the polymer backbone. The pendant groups include acid labile groups and crosslinking groups. The method further includes performing a baking process to cause a crosslinking reaction of the crosslinking groups, thereby forming a crosslinked coating layer. The method further includes depositing a photoresist layer over the crosslinked coating layer. The method further includes selectively exposing the photoresist layer and the crosslinked coating layer to a patterning radiation. The method further includes developing the selectively exposed photoresist layer and the crosslinked coating layer to form a pattern of openings in the photoresist layer and the crosslinked coating layer.

Another aspect of this description relates to a method for forming a semiconductor device. The method includes depositing a photoresist layer comprising an organometallic compound over a substrate. The method further includes forming a coating layer over the photoresist layer. The coating layer includes a switchable polymer, an acid generator and a quencher. The switchable polymer includes a polymer backbone and pendant acid labile groups and crosslinking groups attached to the polymer backbone. The method further includes heating the coating layer at a crosslinking temperature of the crosslinked groups to form a crosslinked coating layer. The method further includes selectively exposing the photoresist layer and the crosslinked coating layer to a patterning radiation. The method further includes developing the selectively exposed photoresist layer and the crosslinked coating layer to form a patterned crosslinked coating layer and a patterned photoresist layer.

Still another aspect of this description relates to a method for forming a semiconductor device. The method includes applying a coating composition onto a substrate to form a coating layer. The coating composition includes a switchable polymer having a polymer backbone and pendant groups that include one or more acid labile groups, one or more crosslinking groups and one or more optional floating groups attached to the polymer backbone, an acid generator and a solvent. The method further includes heating the substrate and the coating layer to a temperature where the one or more crosslinking groups react to crosslink the switchable polymer. The method further includes forming a photoresist layer over the crosslinked coating layer. The method further includes exposing the photoresist layer and the crosslinked coating layer to radiation through a photomask. The method further includes removing unexposed regions of the photoresist layer and the crosslinked coating layer by a developer to form a patterned photoresist layer and a patterned crosslinked coating layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a coating layer over a substrate, the coating layer comprising a switchable polymer and an acid generator, the switchable polymer comprising a polymer backbone and pendant groups attached to the polymer backbone, wherein the pendant groups include acid labile groups and crosslinking groups;
performing a baking process to cause a crosslinking reaction of the crosslinking groups, thereby forming a crosslinked coating layer;
depositing a photoresist layer over the crosslinked coating layer;
selectively exposing the photoresist layer and the crosslinked coating layer to a patterning radiation; and
developing the selectively exposed photoresist layer and the crosslinked coating layer to form a pattern of openings in the photoresist layer and the crosslinked coating layer.

2. The method of claim 1, wherein the acid generator comprises a photoacid generator or a thermal acid generator.

3. The method of claim 1, wherein the baking process is performed at a temperature that causes crosslinking of the crosslinking groups, but does not cause the cleavage of the acid labile groups.

4. The method of claim 3, wherein the temperature ranges from 80° C. to 200° C.

5. The method of claim 1, wherein the photoresist layer comprises an organometallic compound.

6. The method of claim 1, wherein the coating layer further comprises a quencher.

7. The method of claim 1, wherein the switchable polymer comprises 10-70 wt. % of the acid labile groups and 30-70 wt. % of crosslinking groups.

8. The method of claim 1, wherein the switchable polymer further comprises pendant floating groups attached to the polymer backbone.

9. The method of claim 1, further comprising removing portions of the substrate exposed by the openings.

10. A method for forming a semiconductor device, comprising:
depositing a photoresist layer comprising an organometallic compound over a substrate;
forming a coating layer over the photoresist layer, the coating layer comprising a switchable polymer, an acid generator and a quencher, the switchable polymer comprising a polymer backbone and pendant acid labile groups and crosslinking groups attached to the polymer backbone;
heating the coating layer at a crosslinking temperature of the crosslinked groups to form a crosslinked coating layer;
selectively exposing the photoresist layer and the crosslinked coating layer to a patterning radiation; and
developing the selectively exposed photoresist layer and the crosslinked coating layer to form a patterned crosslinked coating layer and a patterned photoresist layer.

11. The method of claim 10, wherein the patterning radiation is an extreme ultraviolet or an e-beam radiation, the patterning radiation causing the acid generator to generate an acid which causes cleavage of the acid labile groups.

12. The method of claim 11, further comprising etching the substrate using the patterned crosslinked coating layer and the patterned photoresist layer as an etching mask.

13. A method for forming a semiconductor device, comprising:
applying a coating composition onto a substrate to form a coating layer, the coating composition comprising a switchable polymer having a polymer backbone and pendant groups that include one or more acid labile groups, one or more crosslinking groups and one or more optional floating groups attached to the polymer backbone, an acid generator and a solvent;
heating the substrate and the coating layer to a temperature where the one or more crosslinking groups react to crosslink the switchable polymer, thereby forming a crosslinked coating layer;
forming a photoresist layer over the crosslinked coating layer;
exposing the photoresist layer and the crosslinked coating layer to radiation through a photomask; and
removing unexposed regions of the photoresist layer and the crosslinked coating layer by a developer to form a patterned photoresist layer and a patterned crosslinked coating layer.

14. The method of claim 13, wherein the switchable polymer has the following structure (I): 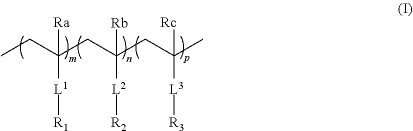
wherein:
L¹, L², and L³ are, at each occurrence, independently a direct bond or an C₁₋₁₀ alkylene, C₁₋₁₀ heteroalkylene, arylene, heteroarylene or heteroatom linker;
Rₐ, R_{b}, and R_{c} are, at each occurrence, independently hydrogen, C₁₋₁₀ alkyl or halogen;
R¹ is, at each occurrence, an acid labile group;
R² is, at each occurrence, a crosslinking group;
R³ is, at each occurrence, a floating group;
m and n are independently an integer of 1 or greater; and
p is an integer of 0 or greater.

15. The method of claim 14, wherein Rₐ, R_{b}, and R_{c} are independently hydrogen or methyl.

16. The method of claim 14, wherein R¹ has one of the following structures:

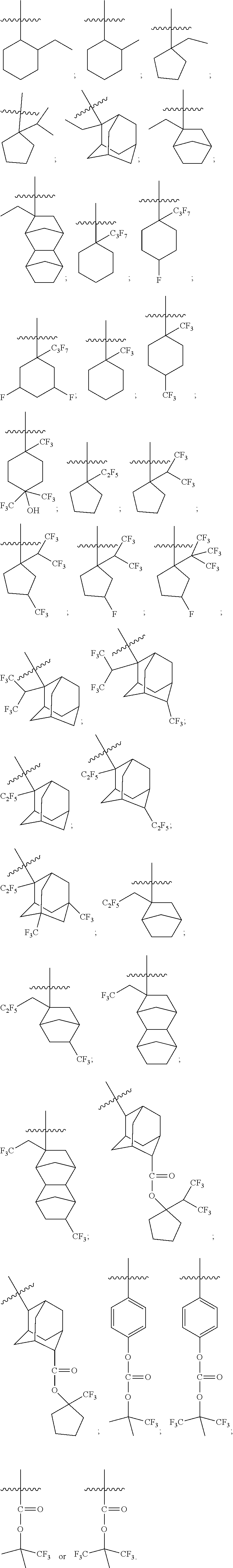

17. The method of claim 14, wherein R² has one of the following structures: 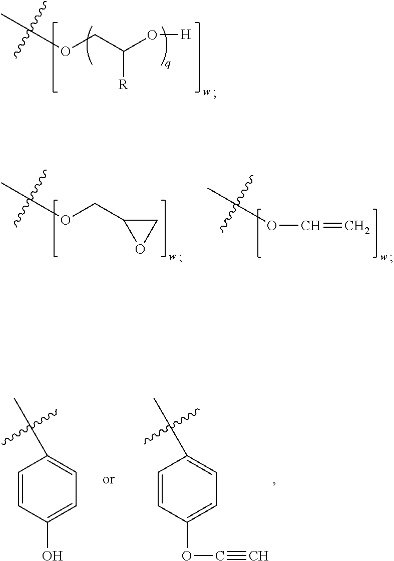
wherein:
R is, at each occurrence, hydrogen or an alkyl group having 1 to 10 carbons atom(s);
q is an integer of 1 to 300; and
w is an integer of 1 to 6.

18. The method of claim 14, wherein R³ has one of the following structures:

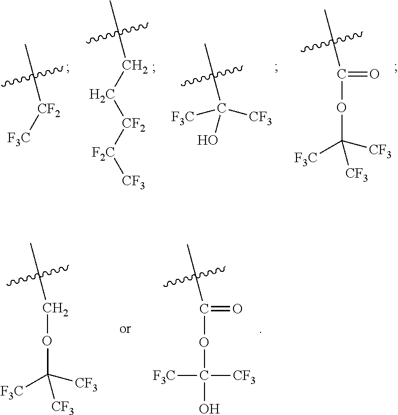 [SMILES: *C(F)(F)C(F)(F)F ; *CCC(F)(F)C(F)(F)C(F)(F)F ; *C(O)(C(F)(F)F)C(F)(F)F ; *C(=O)OC(C(F)(F)F)(C(F)(F)F)C(F)(F)F ; *COC(C(F)(F)F)(C(F)(F)F)C(F)(F)F ; *C(=O)OC(O)(C(F)(F)F)C(F)(F)F]

19. The method of claim 14, wherein L¹, L², and L³ are independently a saturated C1-C9 cyclic or non-cyclic group unsubstituted or substituted with halogen, —S—, —P—, —P(O₂)—, —C(═O)S—, —C(═O)O—, —O—,—N—,—C(═O)N—,—SO₂O—,—SO₂S—, —SO—,—SO₂—, —C₆H₆—O—, —C₆H₆—O—C(═O)O—, an ether group, a ketone group, an ester group or a phenylene group.

20. The method of claim 14, wherein L¹, L², and L³ are independently have one of the following structures: 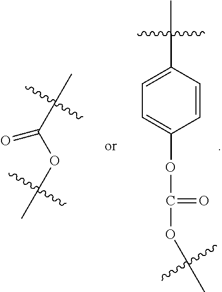 [SMILES: *OC(*)=O ; *OC(=O)Oc1ccc(*)cc1]
